(19) United States
(12) Patent Application Publication
(10) Pub. No.: US 2003/0160268 A1
(43) Pub. Date: Aug. 28, 2003

(54) Semiconductor chip, method and apparatus for fabricating the semiconductor chip

(76) Inventors: Michael Wagner, Oberschweinbach (DE); Manfred Selz, Neubiberg (DE)

Correspondence Address: LERNER AND GREENBERG, P.A., Post Office Box 2480, Hollywood, FL, 33022-2480, US

(21) Appl. No.: 10/376,884

(22) Filed: Feb. 28, 2003

(30) Foreign Application Priority Data
Feb. 28, 2002 (DE) 102 09 073.4

(51) Int. Cl. H01L 21/82; H01L 27/10

(52) U.S. Cl. 257/207; 438/128; 438/129; 257/208; 257/210; 257/211

(57) ABSTRACT

A semiconductor chip has standard cells which are disposed in a plurality of mutually adjacent rows, wiring channels are disposed between the rows and at at least one location along at least one wiring channel, the width of the wiring channel determined by a prescribed unambiguous and variable assignment specification. The width of the wiring channels can thus be varied in a flexible manner, so that a circuit can be fabricated in a space-saving manner.

### BACKGROUND OF THE INVENTION

### Field of the Invention

The invention relates to a semiconductor chip having standard cells which are disposed in a plurality of mutually adjacent rows and wiring channels disposed between the rows.

Standard cells are used for accelerating the design time of a semiconductor chip. The standard cells are, by way of example, gates, shift registers or other digital or analog modules that are formed from individual integrated components, such as transistors, diodes or resistors, and generally provide one or a plurality of standardized functions. Besides standard cells, there are usually also other elements disposed on the semiconductor chips.

The standard cells are usually disposed in a plurality of mutually adjacent rows. The standard cells of a row are supplied with current by tracks disposed along the row. Depending on the number of voltages or currents required within the row, two or further tracks for power supply extend along the rows. The associated power supply tracks of each row are connected to one another and further elements or terminals of the semiconductor chip.

In addition, provision is usually made of further tracks, in particular for transmitting analog or digital signals between the standard cells or to terminals of the semiconductor chip. The tracks are disposed in one or generally in a plurality of so-called metalization planes. The wiring planes can be utilized, besides metallic connections, also for the configuration of optical tracks, in particular optical conductors.

In order to dispose the tracks optimally, a so-called router program is used which connects the inputs and outputs of the standard cells to one another and to terminals of the semiconductor chip. The respective position or the course of the individual tracks is subsequently disentangled in order to enable the densest possible configuration of the standard cells, or of the tracks, and the shortest possible signal delay. Besides this known configuration of standard cells and the wiring thereof, further configuration specifications, for example a vertical or functionally related configuration, for example for isolating a digital and an analog region of an ASIC or the like, are conceivable, of course.

In the known methods, it is not possible to adapt the width of the wiring channels to the respective conditions, which is disadvantageous particularly in the case of accumulations of wiring crossings.

### SUMMARY OF THE INVENTION

It is accordingly an object of the invention to provide a semiconductor chip, a method and an apparatus for fabricating the semiconductor chip that overcome the above-mentioned disadvantages of the prior art devices and methods of this general type, in which the width of the wiring channels can be varied in a flexible manner.

With the foregoing and other objects in view there is provided, in accordance with the invention, a semiconductor chip. The semiconductor chip contains standard cells disposed in a plurality of mutually adjacent rows, and wiring channels disposed between the rows. At at least one location along at least one of the wiring channels, a width of the wiring channel is determined by a prescribed unambiguous and variable assignment specification. The assignment specification is configured as a functional relationship, a table with prescribed values, a correlation, at least one linear function, at least one polygon progression, and/or a polynomial.

According to the invention, the width of at least one wiring channel for standard cells on a semiconductor chip is determined at at least one location, by a prescribed unambiguous and variable assignment specification. The variable assignment specification is in this case understood to mean that the width can be varied by the assignment specification in a manner deviating from a constant width. It is thus possible to produce a circuit in a particularly space-saving manner.

It is advantageous if the unambiguous, variable assignment specification is configured as a functional relationship, as a table with prescribed values, and/or as a correlation. It is thus possible to react flexibly in accordance with the design stipulations respectively present. When using a table, values determined e.g. by design stipulations or simulations can be used for the width without a functional relationship having to be known. Geometries that are particularly simple to realize are produced if the assignment specification has at least one linear function, at least one polygon progression and/or a polynomial.

For simple production, it is advantageous if, in the case of at least one wiring channel, at least one width determined by the unambiguous assignment specification is disposed symmetrically with respect to the longitudinal axis of the wiring channel. It is also advantageous if the width of at least one wiring channel is determined in a manner dependent on the vertical position of the location.

Furthermore, it is advantageous for simple fabrication if the contour—formed by the widths—of at least one wiring channel is disposed symmetrically with respect to a horizontal axis.

It is particularly advantageous if the width of at least one wiring channel is determined by an assignment specification in a manner dependent on the crossing density of wirings in the wiring channel. It is thus possible for the wiring channel to be made widest where there is the greatest space requirement. In this case, it is advantageous if, in at least one wiring channel, the maximum width is disposed in the region of the maximum crossing density.

In an advantageous manner, the tracks for the power supply of the standard cells of at least one row of standard cells are shortened in such a way that the tracks end in the region of a standard cell at the edge of the row. The shortening produces space for additional elements of the integrated semiconductor chip. In particular, this space is utilized for further wirings of standard cells; as an alternative, capacitance or inductances can also be integrated in this space that has been produced.

The power supply tracks are preferably shortened in such a way that, with the inclusion of process fluctuations, the standard cells at the edge of the row are reliably supplied with current by the provision of an overlap region between the power supply terminals of the standard cell and the tracks for power supply. For this purpose, in one advantageous development of the invention, the tracks end within the standard cell at the edge of the row.

In order to simplify the calculation and to ensure a power supply under worse case conditions, in an alternative configuration of the invention, the shortened tracks for power supply may project beyond the edge of the outer standard cell of a row by a tolerance compensation region of a few μm.

In one advantageous development of the invention, the ends of the tracks for power supply are adjoined by a region in which one or a plurality of signal tracks are disposed. In this region, according to the invention, the signal tracks are also disposed in the wiring plane of the power supply tracks, so that wirings are also made possible by the signal tracks transversely with respect to the direction of the rows in the regions. The signal tracks serve for transmitting signals between the standard cells or the terminals of the semiconductor chip.

If the design of the semiconductor chip is configured flexibly such that the density of the configuration of the standard cells is not critical, such as, for example, in the integration of analog circuits that are particularly immune to interference, in an alternative configuration of the invention, the standard cells within one row are positioned with respect to one or a plurality of corresponding standard cells of another row in order to shorten the tracks for transmitting time-critical signals between the standard cells.

If, by contrast, a particularly dense configuration of the standard cells is desirable, or only few, for example two, wiring planes are available, in one advantageous development of the invention, the standard cells within a row are disposed adjacent to one another in such a way that interspaces between the standard cells are reduced.

According to the invention, a prescribed and variable assignment specification for the width of at least one wiring channel at at least one location along the wiring channel is evaluated. Then at least one standard cell and/or at least one row are disposed laterally in such a way that the at least one wiring channel has in each case the width in accordance with the assignment specification at the location.

In this case, standard cells are disposed within a plurality of mutually adjacent rows and each standard cell is connected by a plurality of tracks for connection to other elements of the semiconductor chip and/or terminals of the semiconductor chip. Then a power supply region of at least one of the outer standard cells of the respective row is determined. Then a configuration of tracks for power supply up to this power supply region of the standard cell is determined.

In an advantageous method for fabricating the semiconductor chip described above, standard cells are disposed in a plurality of mutually adjacent rows and each standard cell is connected by a plurality of tracks for connection to other elements of the semiconductor chip and/or terminals of the semiconductor chip. Tracks for power supply are preferably disposed along the row of the standard cells and in each case supply the standard cells of a row with current or different supply voltages.

A power supply region of at least one of the outer standard cells of the row is determined by a procedure in which, in particular, the position of the power supply terminals, that is to say the connection points to the individual elements of the standard cell, such as transistors, diodes or the like, is determined. A configuration of the tracks for power supply up to the power supply region of the standard cell is subsequently determined, so that the power supply terminals are positioned with respect to the tracks for power supply and ensure a reliable power supply. For this purpose, in one configuration of the invention, the power supply region ends within the outer standard cell of the row.

In order to simplify the method computationally, in one advantageous development of the method, the outer edge of the standard cell is determined and the entire region of the standard cell is defined as the power supply region, so that the power supply region ends at the outer edge of the outer standard cell of the row. The edge region of the standard cell can be determined particularly simply for this purpose.

One advantageous configuration of the invention provides for a region for power supply up to the outer standard cell of the row to be determined by a procedure in which each standard cell of the present row is compared with an outer maximum position. The initial value of the maximum position is prescribed at the beginning preferably in the central region of the row. For the comparison, the coordinates of the present standard cell in the direction of the row length are compared with the coordinate of the maximum position in the same direction.

In the event of the outer maximum position being exceeded by the power supply region of the present standard cell, in particular if the coordinates of the standard cells exceed the coordinate of the maximum position, the maximum position is redefined to the power supply region of the standard cell. For the definition, by way of example, the coordinate of the maximum position is set to be equal to the outer coordinate of the standard cell.

After the last comparison of the present row, the region for the power supply of the present row up to the last maximum value is set, so that the power supply tracks extend up to the coordinate of the last maximum value.

Once the power supply region of the outer standard cell of the row has been determined, it is preferably stored or made available for further evaluation in some other way. The region adjoining the power supply region can subsequently be determined and used as a place holder for a subsequent wiring (routing). In one advantageous configuration of the method, in this region, in the wiring plane of the tracks for power supply, the configuration of signal tracks for transmitting signals to other elements of the semiconductor chip and/or terminals of the semiconductor chip is determined.

By way of example, suitable software or hardware that is specialized for a configuration of the wiring is used for carrying out the method. The software and the hardware can also be integrated into an overall system that enables the fabrication of intermediate products, for example of exposure masks with the structures according to the invention.

Other features which are considered as characteristic for the invention are set forth in the appended claims.

Although the invention is illustrated and described herein as embodied in a semiconductor chip, a method and an apparatus for fabricating the semiconductor chip, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is an illustration of a semiconductor chip with standard cells disposed in rows in accordance with the prior art;

FIG. 1A is a detailed illustration of a part of FIG. 1;

FIG. 2 is a diagrammatic illustration of a wiring channel between two rows of standard cells according to the invention;

FIGS. 2A-2D illustrate four configurations with different contours of the wiring channel according to the invention;

FIG. 3A is a diagrammatic illustration of three columns of standard cells with two wiring channels, the columns each having concave contours according to the invention;

FIG. 3B is a diagrammatic illustration of three columns of standard cells with two wiring channels, the columns being straight at the outer sides according to the invention;

FIG. 4 is a program flowchart for fabricating a semiconductor chip according to the invention;

FIG. 4A is a diagrammatic illustration of rows of standard cells without wiring channels according to the invention;

FIG. 5 is an illustration of a semiconductor chip with columns modified according to the invention;

FIG. 5A is a detailed illustration of a part of FIG. 5; and

FIG. 6 is a flow chart explaining a method sequence for the wiring of a semiconductor chip according to the invention.

### DESCRIPTION OF THE PREFERRED EMBODIMENTS

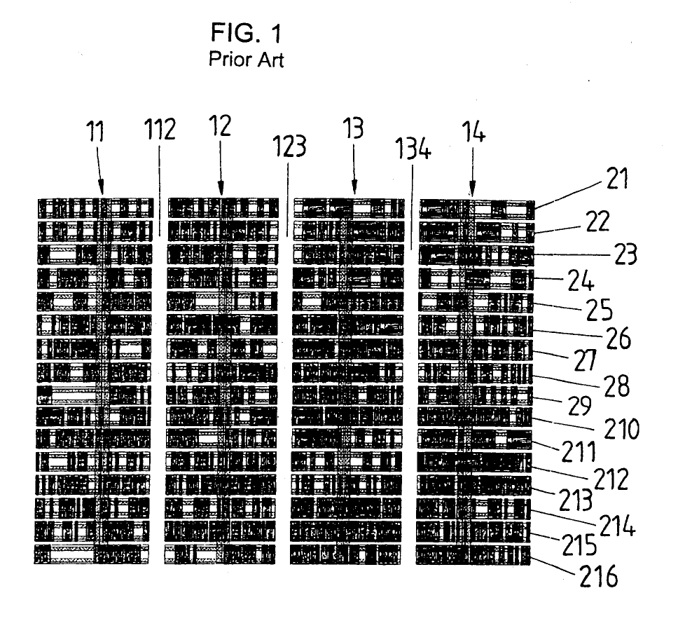

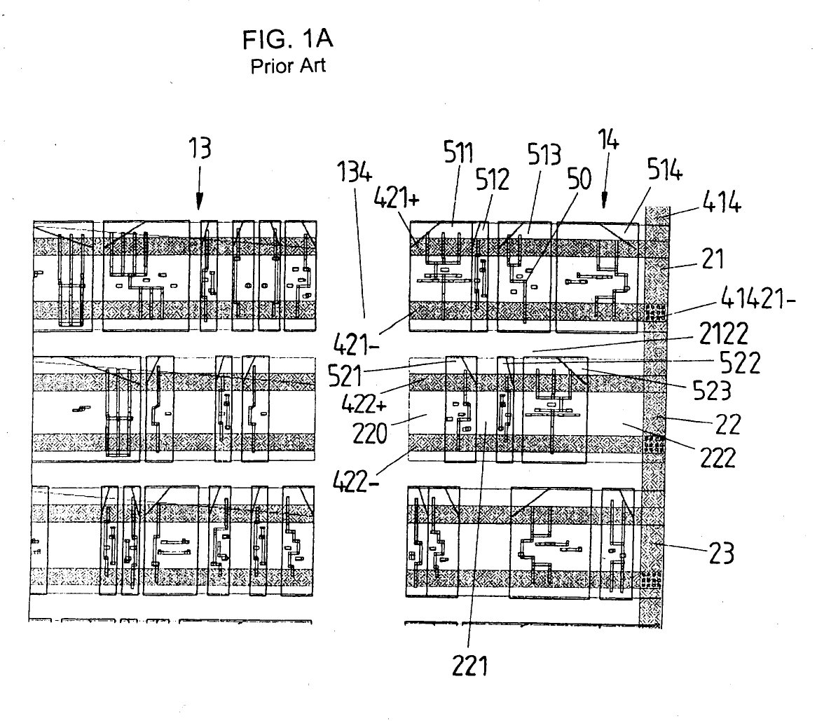

Referring now to the figures of the drawing in detail and first, particularly, to FIGS. 1 and 1A thereof, there are shown standard cells in a structure of a semiconductor chip in accordance with the prior art.

In this example, provision is made of four columns 11, 12, 13, 14 having a plurality of rows 21 to 216 with standard cells 511, 512, 513, 514, etc. The standard cells 511, etc. are, for example, gates, shift registers or other digital or analog modules that are predefined as standard. The predefinition specifies how individual integrated components, such as transistors, diodes or resistors, are connected up.

By virtue of the cell structure, the external dimensions of the respective standard cell are fixedly prescribed here but, for different standard cells 511, 512, etc., may deviate significantly from one another in terms of width, as shown by the illustration of the standard cells 511 and 512 of FIG. 1A. The standard cells 511, etc. generally provide one or a plurality of standardized functions. In this example, the height of the standard cells 511, etc. is likewise fixedly prescribed, so that the height does not vary within a row 21, etc.

The standard cells 511 to 514 and 521 to 523 of a row 21 and 22, respectively, are connected by power supply tracks 421+, 421−, 422+ and 422−, etc. to terminals or functional units of the semiconductor chip for supplying the respective standard cell 511, etc. with required power. For this purpose, the power supply tracks 421+, 421−, 422+ and 422− etc. of all the rows 21 and, respectively, 22, etc. of a column 11, 12, 13, 14 are connected to column supply tracks 414 via contact regions 41421− (pin through), which are preferably disposed in the center of the rows 21, etc. over the entire height of the respective column 14, etc.

For signal transmissions or for connecting potentials, tracks 50 are provided within a standard cell 513, etc. which connect individual components, such as the gate of a transistor and a diode, etc., of a standard cell 513 to one another. Furthermore, the standard cells 513, etc. are connected to one another or to terminals of the semiconductor chip. For these connections, use is made of signal tracks that, like the rest of the tracks, are formed by metal tracks within one or a plurality of metallization planes.

Between the rows 21, etc. oriented horizontally in linear form, provision is made of spacer regions 2122 between the standard cells 51, etc. of two rows 21, 22, which can be utilized for horizontal wiring.

Vertical wiring channels 112, 123, 134 within which no standard cells are disposed are provided between the individual columns 11 to 14. The wiring channels 112, 123, 134 are utilized for vertical wiring in order to connect standard cells 511, etc. of different rows and/or columns to one another, in order to transmit signals or to connect potentials or, by way of example, control terminals between the standard cells to one another.

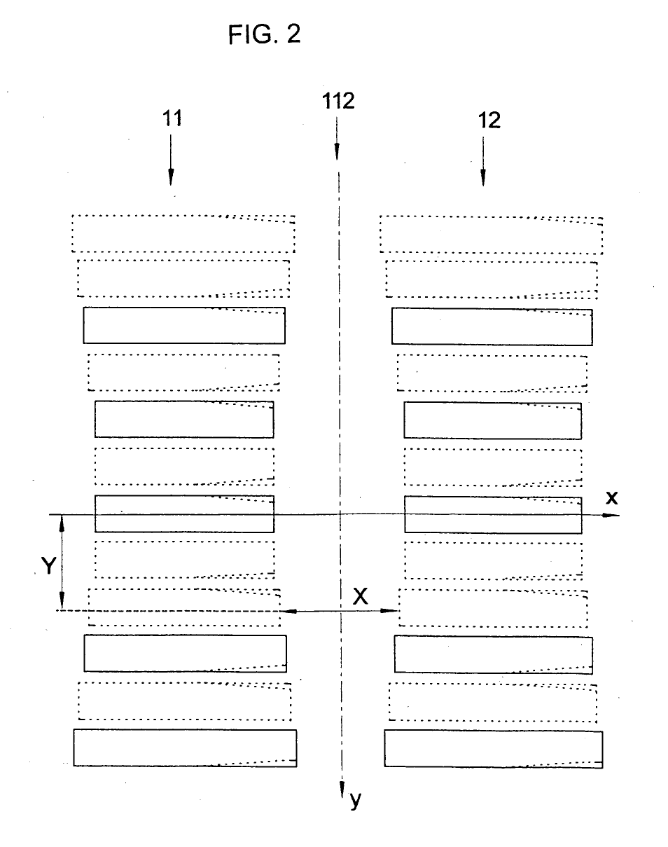

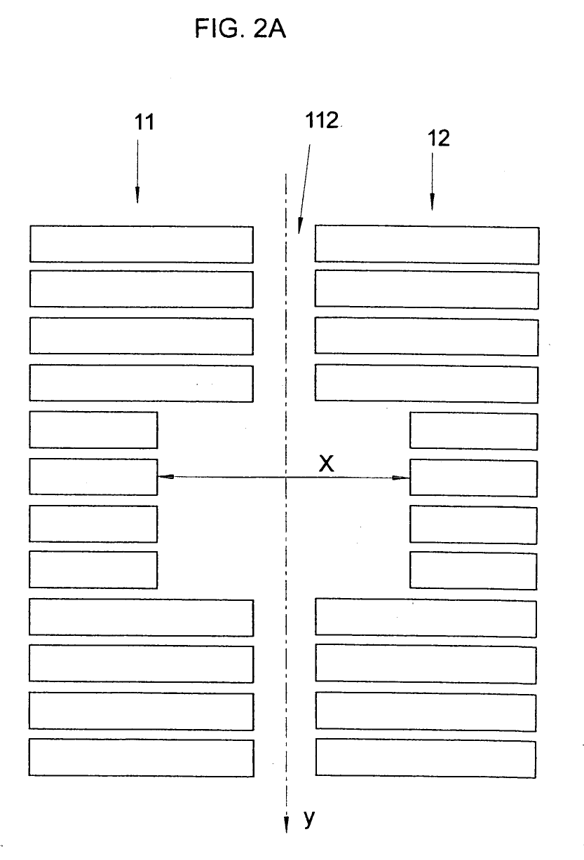

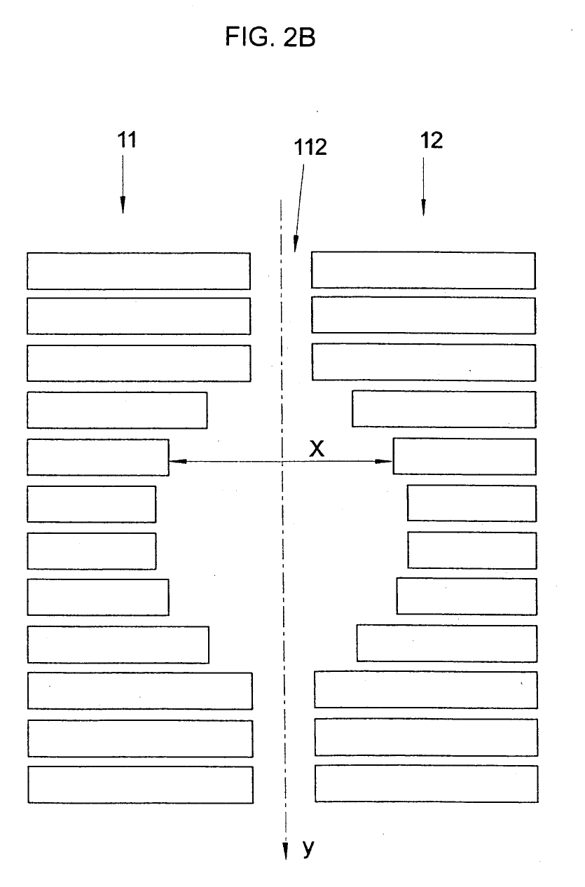

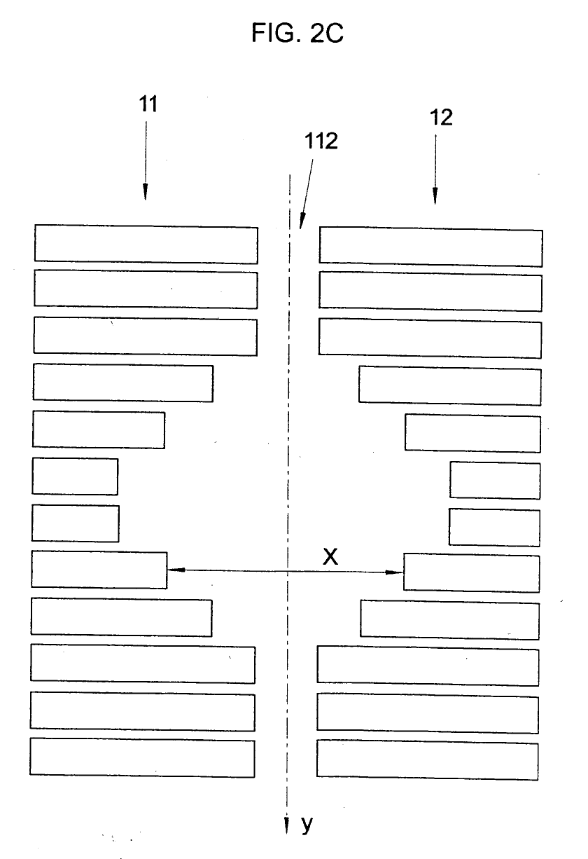

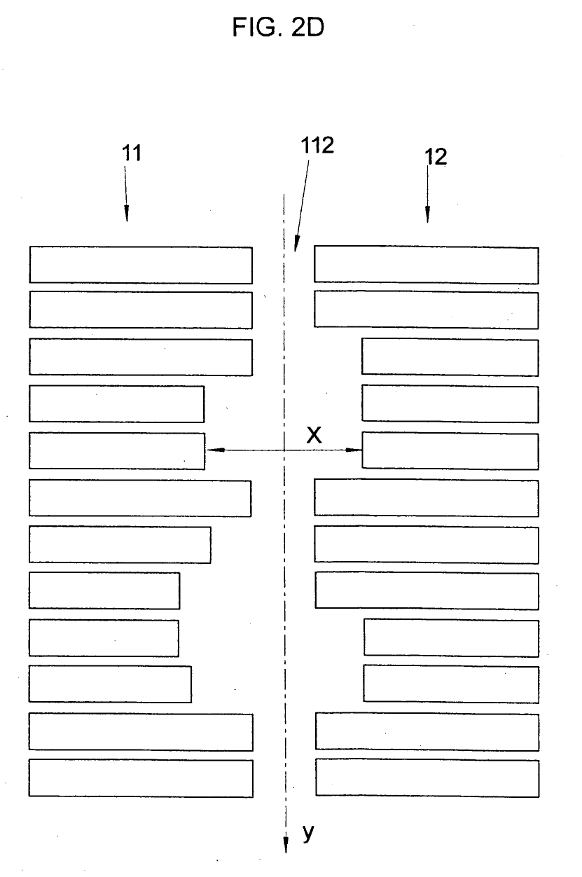

The configuration of the wiring channel 112 according to the invention is illustrated in FIG. 2. Analogously to FIG. 1, the wiring channel 112 is disposed between two columns 11, 12. Two axes are depicted in FIG. 2 for defining the geometry. A vertical y-axis extends in a longitudinal direction of the wiring channel 112, and a horizontal x-axis extends at right angles thereto. A width X of the wiring channel 112 is accordingly determined in the horizontal extent. The position of the location Y at which a specific width X is disposed can be defined on the basis of the y-axis.

According to the invention, at at least one location Y along at least one wiring channel 112, the width X of the wiring channel is determined by a prescribed unambiguous assignment specification.

In this case, an assignment specification is understood to mean any type of unambiguous dimensioning principle for determining at least one width X of the wiring channel 112. Simple assignment specifications are e.g. linear or piecewise linear (polygon progression). It is also possible to store numerical values for the determination of the width X in a table or in vector form. Nonlinear assignment specifications may relate e.g. to polynomials which would result in curved lateral contours of the wiring channel 112. The width X can also be determined by combinations of the assignment specifications.

It should be noted that the width X is in each case determined in discrete regions, namely in the regions of the rows of the standard cells. In other words, if e.g. a continuous polynomial is used as assignment specification, then the polynomial is only evaluated at a few support points which each have the commensurate distance determined by the rows.

If the assignment specification depends on the x and/or y coordinates, then the following would hold true for the assignment specification F

X:=F(x,y)

In FIG. 2, the width X first increases in the positive y-direction, reaches a maximum in the center between the rows and then decreases again. The function of the width X depending on the vertical position would correspond here to a downwardly open parabola.

The width X is set here in such a way that the rows and/or the individual standard cells are automatically erased, displaced and/or interrupted in such a way as to produce the predetermined width X.

An aim of the configuration is to create the widest possible wiring channel 112 here in the central region. The wirings between the rows, which wirings are not illustrated here for reasons of clarity, naturally cross in the center, so that the largest clearance in the wiring channel 112 is required here.

This can also be achieved automatically by the crossing density along the wiring channel 112 being calculated by the routing program. This information can then be used directly as assignment specification by the width X being determined proportionally to the crossing density. The calculated values can then be stored in a vector.

The form of the wiring channel 112 as illustrated in FIG. 2 is axially symmetrical with respect to the x and y-axes. This need not necessarily be so.

FIGS. 2A to 2D diagrammatically illustrate other geometries in which the width X is determined in a different way. Thus, the width of the wiring channel 112 can be adapted e.g. to the respective crossing density of the wirings.

In FIG. 2A, the wiring channel 112 is abruptly widened and tapered again at one location. A rectangular widening is produced. Here the assignment specification would contain a vector having two different values for determining the width X, e.g.

F=(0, 0, 1, 1, 1, 1, 0, 0, 0).

In a modification of the example in FIG. 2A, FIG. 2B illustrates a rounded widening and tapering.

An assignment specification composed of linear sections has been realized in FIG. 2C, thereby producing a rhomboidal widening.

FIG. 2D illustrates that the widenings do not have to be disposed only at one location and also do not have to be symmetrical with respect to the x- and/or y-axis. The different widths X can be determined by a function that is defined in sections, the values of which function are then stored in a two-dimensional vector. For each width X, on account of the asymmetry, it is then necessary also to define a start value in the x direction (e.g. beginning of the width X or midpoint).

It should be noted that the blocks or columns separated by the wiring channels 112 need not necessarily have the same width, but rather can also have different widths.

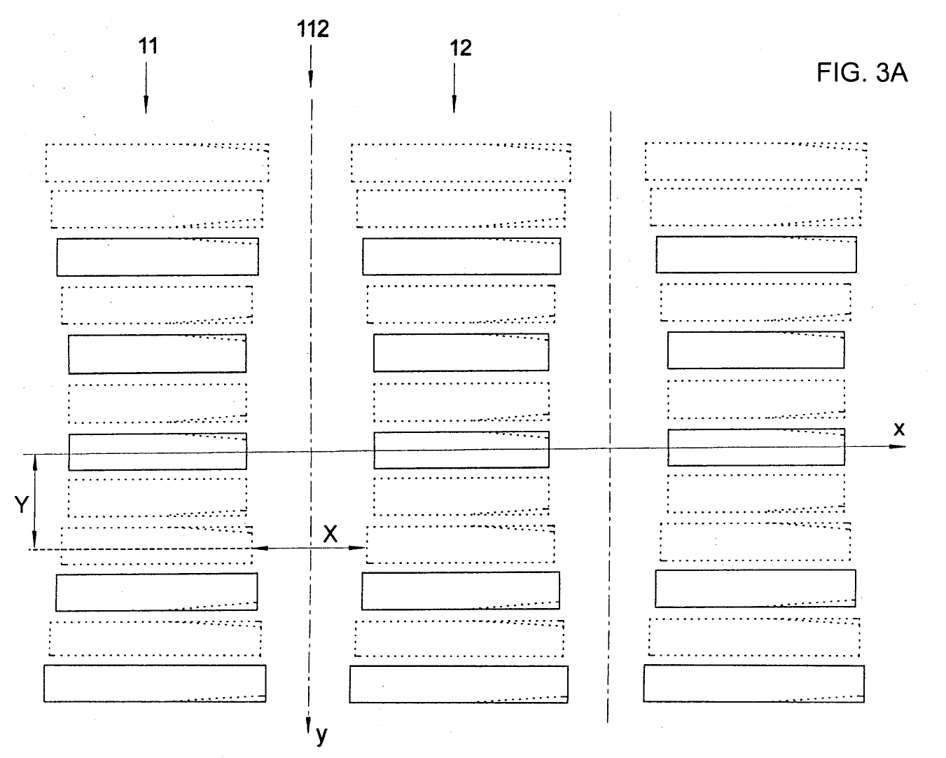

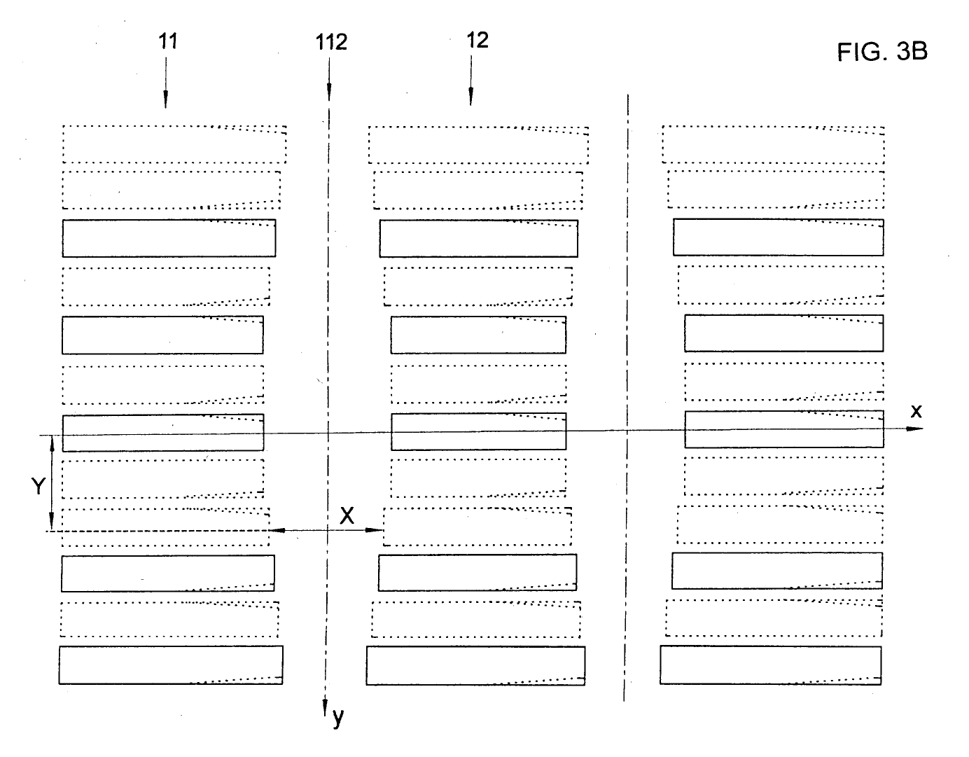

FIG. 3A diagrammatically illustrates three columns 11, 12, 13 with two wiring channels 112, 123. In this case, the outer contour of the columns is in each case slightly rounded at both sides.

FIG. 3B fundamentally illustrates the same situation, but here the columns 11, 12, 13 are made straight at the right-hand and left-hand outer sides.

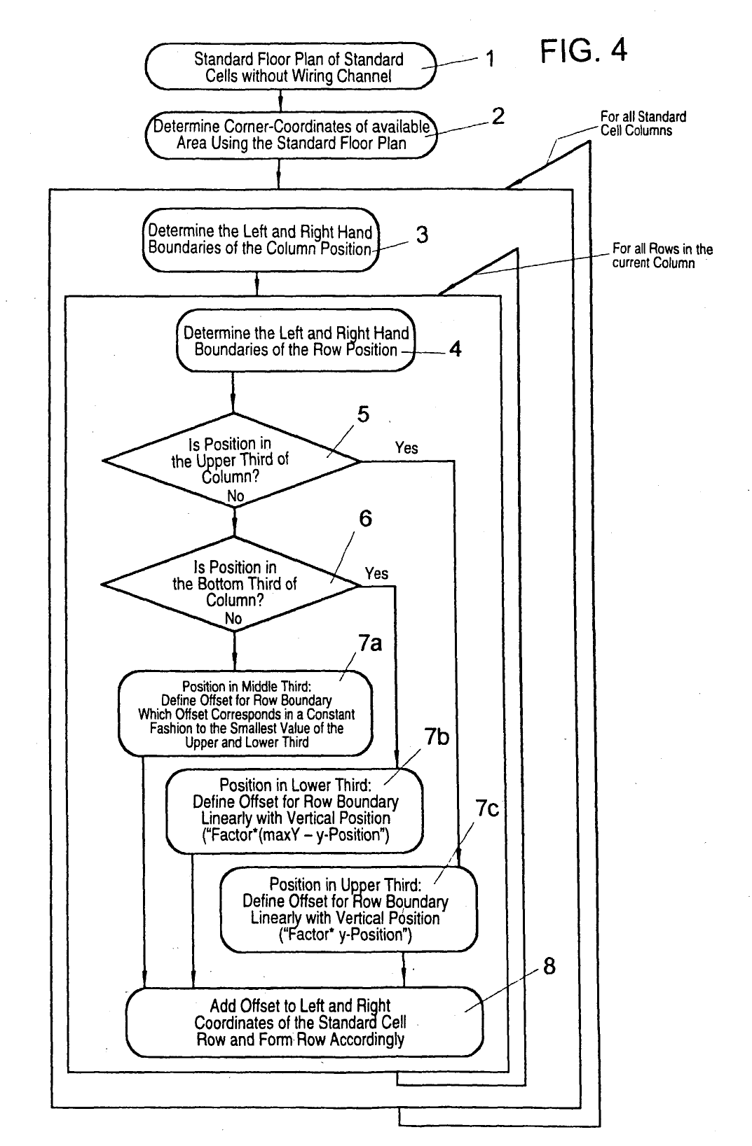

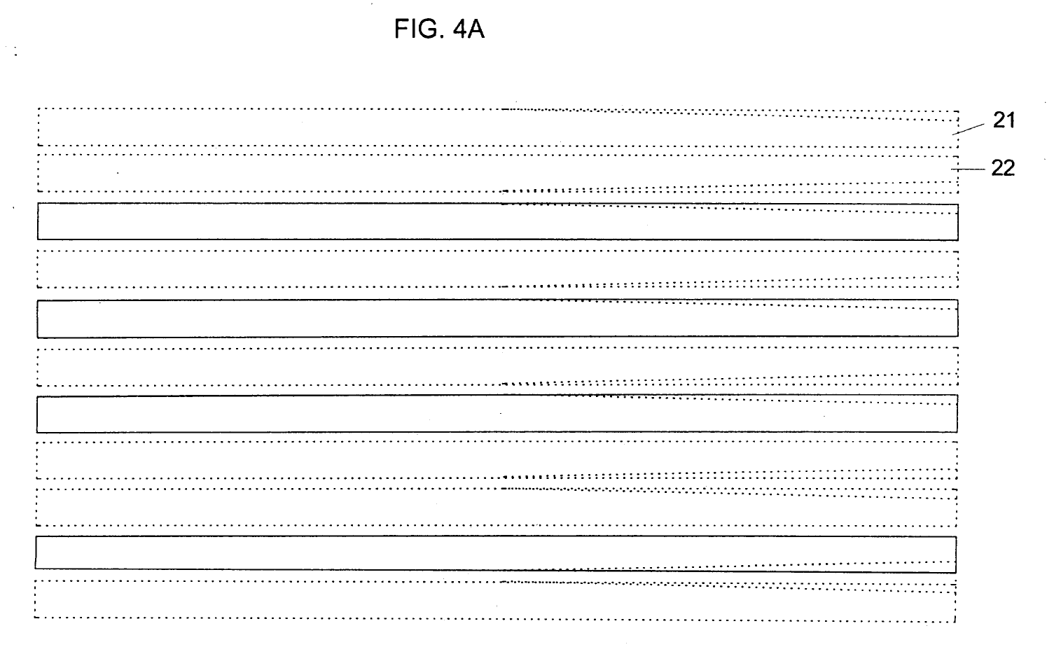

FIG. 4 illustrates a program flowchart for an embodiment of the method according to the invention. It should be noted that the method according to the invention which is described here constitutes only part of the otherwise known fabrication method for semiconductor chips.

The starting point is a first method step 1, in which a standard floor plan with a configuration of the standard cells without wiring channels 112, 123, 134, 112′, 123′, 134′ is created. This is illustrated in FIG. 4A.

Afterward, in a second method step 2, the corner coordinates of the available area are determined automatically using the standard floor plan.

The third method step 3 represents the entry into a loop that is iterated for all standard cell columns.

Within the outer loop, an inner loop is iterated for all present rows (if appropriate columns as well).

In the fourth method step 4, the left-hand and right-hand boundaries of the wiring channel 112, 123, 134, 112′, 123′, 134′ at this location are calculated from the user stipulations and the present vertical linear position.

In the fifth method step 5, a check is made to determine whether the position of the row currently being examined is situated in the upper third of the column.

If this check turns out to be negative, in the sixth method step 6 a check is made to determine whether the position of the row currently being examined is situated in the lower third of the column.

If this check turns out to be negative, i.e. the row lies in the central third, then, in the first variant of the seventh method step 7a, an offset is defined for the row boundaries, which offset corresponds in a constant fashion to the smallest value of the upper and lower thirds. The assignment specification thus corresponds to a constant in the central third. The width X of the wiring channel 112, 123, 134, 112′, 123′, 134′ is defined by way of the offsets.

Afterward, in the eighth method step 8, the calculated offset is added to the right and left x-coordinate of the respectively calculated standard cell row and the row is formed accordingly. This is followed by a return for determining the width X in the next row.

In this case, a small offset means that, in the region of the central third, the wiring channel 112, 123, 134, 112′, 123′, 134′ is altered only a little relative to a stipulation.

In the upper and lower thirds, by contrast, the offsets are altered by a linear function.

The second alternative of the seventh method step 7b concerns the case where the position lies in the lower third. The offset for the row boundary is then determined by a linear assignment specification

Factor*(max Y−y-position)

depending on the y-coordinate.

Accordingly, the assignment specification in accordance with the third alternative of the seventh method step 7c for the upper third reads

Factor*y-position.

A wiring channel that essentially has the contour of a polygon progression that is symmetrical with respect to the y-axis is thus obtained.

By varying the assignment specifications, it is also possible to generate other geometries that are adapted to the respective purpose.

After the inner loop has been iterated, a return is made to the outer loop.

The termination criterion, which is not illustrated here, is a check to determine whether all the columns and rows have been encompassed by the algorithm.

The text below describes advantageous configurations in which the tracks for power supply are concomitantly included in the fashioning of the wiring channels.

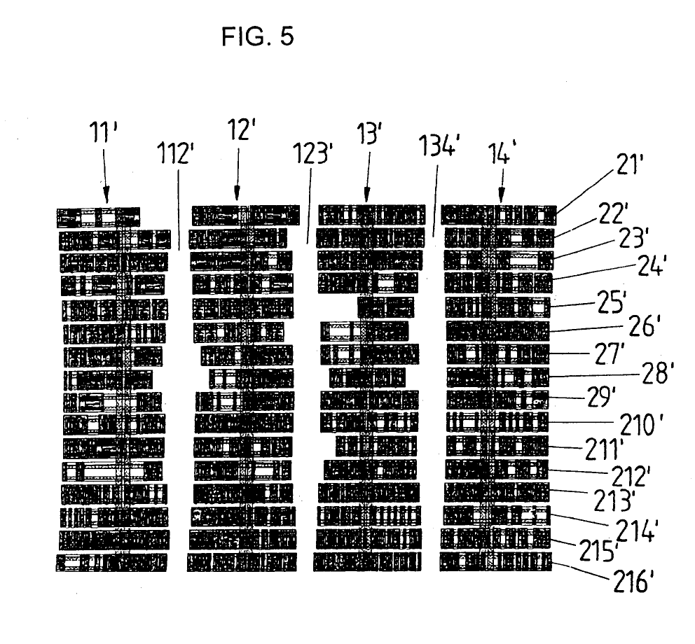

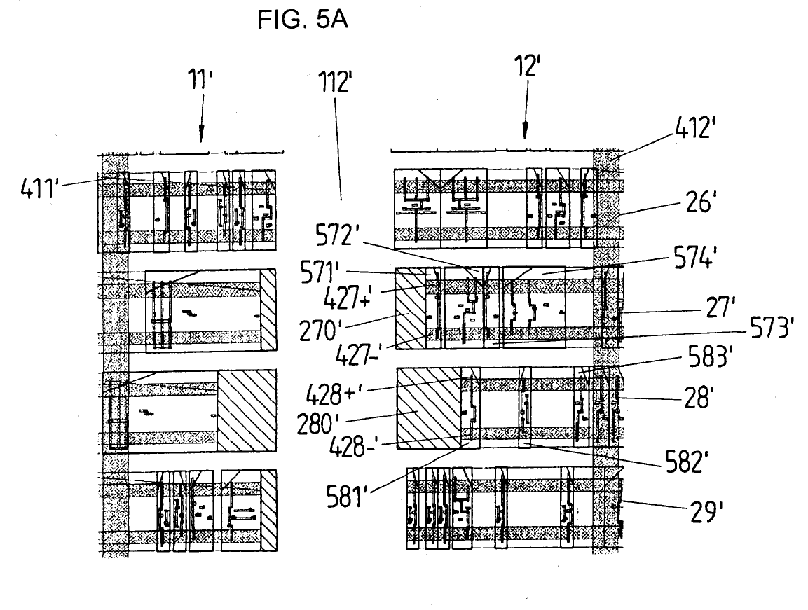

One advantageous configuration of the invention is illustrated in FIGS. 5 and 5A. In this case, the above-mentioned configuration of the wiring channels 112′, 123′, 134′ according to the invention is used and then the width of rows 21′ to 216′ of the columns 11′ to 14′ is significantly reduced. As a result of the reduction of the width of the rows 21′ to 216′, the wiring channels 112′, 123′, 134′ are again widened significantly, so that a number of vertical connections within the wiring channels 112′, 123′, 134′ can be increased.

For this purpose, in a region 220 extending beyond the outer standard cell 521, as is illustrated in FIG. 1A, the tracks for power supply 422+ and 422− are shortened. Such a shortening is illustrated in FIG. 5A. The wiring channel 112′ between the columns 11′ and 12′ is widened at least line by line by virtue of the fact that the regions 270′, 280′ of the rows 27′ and 28′ which project beyond the outer standard cell have no power supply tracks 427+′, 427−′, 428+′ and 428−′. These regions 270′, 280′ can thus additionally be utilized for a vertical or else horizontal wiring.

In addition, in an embodiment that is not illustrated, the regions 221, 222 (illustrated in FIG. 1A) between the standard cells 522, 523, etc. are decreased by the standard cells 522, 523, etc. being disposed adjacent to one another. This is advantageous in particular when a positioning of the standard cells 522, 523, etc. that is flexible in specific regions is possible, so that the wiring (routing) is influenced only insignificantly by this.

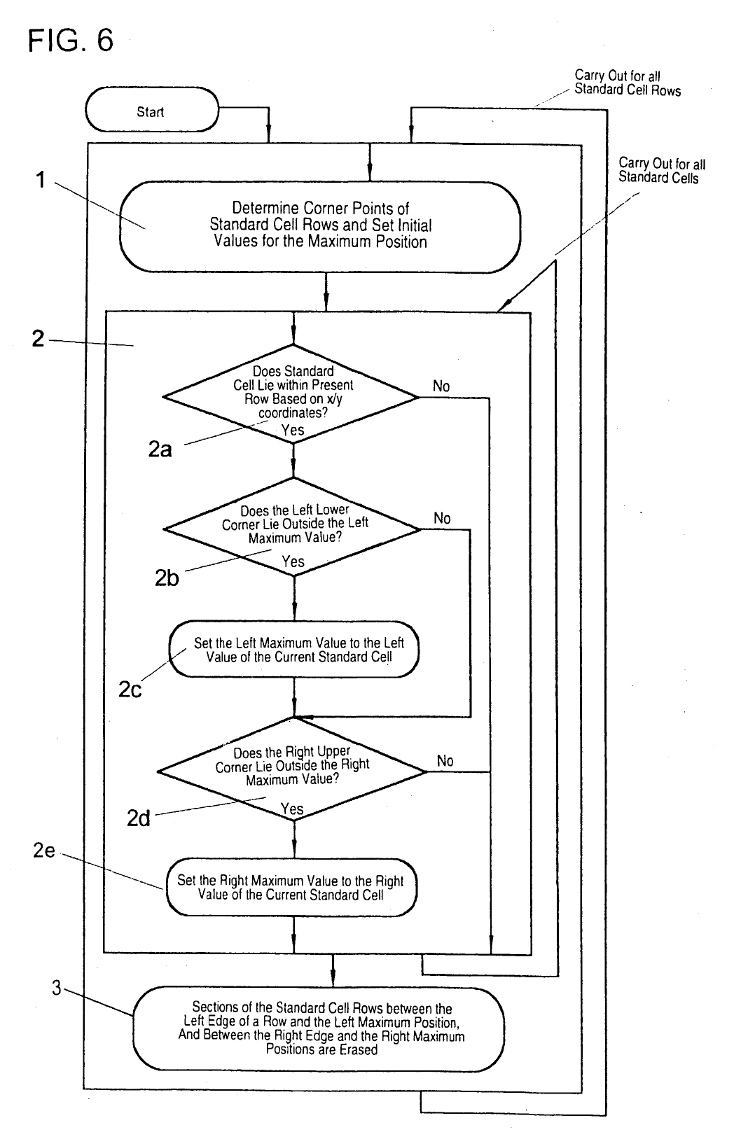

FIG. 6 shows a diagrammatic illustration of part of a method sequence for the wiring of the semiconductor chip. After the start of the sequence, in step 1, the corner points of the present standard cell row are determined. In addition, for this row, the left maximum position and the right maximum position are set relating to the center of the standard cell row as an initial value. In step 2, each standard cell SC is compared with the corner points in order to determine whether the present standard cell SC is situated within the present row and whether the present standard cell SC is an outer standard cell SC of the row.

In step 2a, for this purpose, a check is made on the basis of a comparison of x-coordinates and y-coordinates to determine whether the present standard cell SC is situated in the present row. If this is not the case, a further standard cell SC is compared with the corner points. For this purpose, the method sequence preferably has a loop for all standard cells SC to be compared.

If the present standard cell SC is situated within the present row, afterward, in step 2b, a left corner of the present standard cell SC is compared with the present maximum position of the row. If the bottom left corner lies further to the left than the left maximum position, in step 2c the left maximum position is set to the left x-value of the present standard cell SC. In steps 2d and 2e, the steps analogous to steps 2b and 2c are effected for the right maximum position.

Afterward, in accordance with the loop, a further standard cell SC is compared until at least all coordinates of standard cells SC that are relevant to this row have been evaluated.

Afterward, in step 3, the sections of the standard cell rows between the left edge of the row and the left maximum position, and between the right edge of the row and the right maximum position, are erased. This part of the method sequence of steps 1 to 3 is carried out for all standard cell rows by a further loop.

In a departure from this exemplary embodiment, other iterative methods are also conceivable which calculate the shortening of the power supply tracks up to the first (outer) standard cell.

The embodiment of the invention is not restricted to the preferred exemplary embodiments specified above. Rather, a number of variants are conceivable which make use of the semiconductor chip according to the invention or the fabrication method in the case of embodiments of fundamentally different configuration as well, for example a new configuration of standard cells.

We claim:

1. A semiconductor chip, comprising:
standard cells disposed in a plurality of mutually adjacent rows; and
wiring channels disposed between said rows, at at least one location along at least one of said wiring channels, a width of said at least one wiring channel being determined by a prescribed unambiguous and variable assignment specification, the assignment specification configured as at least one of a functional relationship, a table with prescribed values, a correlation, at least one linear function, at least one polygon progression, and a polynomial.

2. The semiconductor chip according to claim 1, wherein said at least one wiring channel having said width determined by the assignment specification is disposed symmetrically with respect to a longitudinal axis of said at least one wiring channel.

3. The semiconductor chip according to claim 1, wherein said width of said at least one wiring channel is determined in a manner dependent on a vertical position of the location.

4. The semiconductor chip according to claim 1, wherein said width is one of a plurality of widths defining a contour of said at least one wiring channel, said contour disposed symmetrically with respect to a horizontal axis.

5. The semiconductor chip according to claim 1, wherein said width of said at least one wiring channel is determined by the assignment specification in a manner dependent on a crossing density of wirings in said at least one wiring channel.

6. The semiconductor chip according to claim 5, wherein said width in one of a plurality of widths of said at least one wiring channel, one of said widths being a maximum value width disposed in a region of a maximum crossing density.

7. The semiconductor chip according to claim 1, further comprising:
terminals; and
a plurality of tracks connected to said standard cells for connecting said standard cells to other elements and to said terminals of the semiconductor chip, said tracks include tracks for supplying power to said standard cells, said tracks for supplying power of at least one of said rows of said standard cells are shortened such that said tracks for supplying power end in a region of a respective standard cell at an edge of said row.

8. The semiconductor chip according to claim 7, wherein said tracks for supplying power end within said respective standard cell at said edge of said row.

9. The semiconductor chip according to claim 7, wherein said tracks include signal tracks serving for transmitting signals between said standard cells and said terminals, said signal tracks disposed in a region adjoining an end of said tracks for supplying power at least in one wiring plane of said tracks for supplying power.

10. The semiconductor chip according to claim 9, wherein in said region in which said signal tracks run, said signal tracks have a course at least in sections perpendicular to said row of said standard cells.

11. The semiconductor chip according to claim 7, wherein said standard cells within one row are positioned with respect to at least one of a corresponding standard cell of another row in order to shorten said tracks transmitting time-critical signals between said standard cells.

12. The semiconductor chip according to claim 7, wherein said standard cells within a respective row are adjacent to one another in order to reduce interspaces between said standard cells.

13. A method for fabricating a semiconductor chip, which comprises the steps of:
evaluating a prescribed, variable assignment specification for defining a width of at least one wiring channel at at least one location along the one wiring channel; and
disposing at least one row of standard cells laterally in such a way that the at least one wiring channel has in each case the width in accordance with the assignment specification at the location.

14. The method according to claim 13, which further comprises:
disposing the standard cells within a plurality of mutually adjacent rows;
using a plurality of tracks for connecting the standard cells to other elements of the semiconductor chip and to terminals of the semiconductor chip;
determining a power supply region of at least one of the standard cells being an outer standard cell of a respective row; and
determining a configuration of the tracks for supplying power up to the power supply region of the outer standard cell.

15. The method according to claim 14, which further comprises forming the power supply region to end at an outer edge of the outer standard cell of the respective row.

16. The method according to claim 14, which further comprises forming the power supply region to end within the outer standard cell of the respective row.

17. The method according to claim 13, which further comprises:
defining a power supply region for each of the standard cells;
determining a region for power supply, which extends up to an outer standard cell of a respective row, by using a procedure in which an outer position of the power supply region of each of the standard cells of the respective row is compared with an outer maximum position; and
redefining the outer maximum position to the outer position of the power supply region of a current standard cell being compared in an event that the outer maximum position is exceeded by the outer position of the power supply region of the current standard cell being compared, and after a last comparison of the respective row the region for power supply of the respective row is set by a last value defining the outer maximum position.

18. The method according to claim 13, which further comprises determining a configuration of signal tracks for transmitting signals to other elements of the semiconductor chip and terminals of the semiconductor chip, the signal tracks disposed in a wiring plane of the tracks for power supply, in a region adjoining the power supply region.

19. The method according to claim 13, which further comprises disposing the standard cells of a row adjacent to one another to reduce interspaces between the standard cells in the row.

20. The method according to claim 13, which further comprises:
defining coordinates for each of the standard cells;
determining a power supply region, which extends up to an outer standard cell of a respective row, by using a procedure in which the coordinates of each of the standard cells of the respective row is compared with an outer maximum position; and
redefining the outer maximum position to the coordinates of a current standard cell being compared in an event that the outer maximum position is exceeded by the coordinates of the current standard cell being compared, and after a last comparison of the respective row the power supply region of the respective row is set by a last value defining the outer maximum position.

21. An apparatus for assisting in fabricating a semiconductor chip, the apparatus comprising:
means for evaluating a prescribed, variable assignment specification, the assignment specification defining a width of at least one wiring channel at at least one location along the one wiring channel; and
means for laterally disposing at least one row of standard cells laterally in such a way that the at least one wiring channel has in each case the width in accordance with the assignment specification at the location.

22. The apparatus according to claim 21, further comprising:
means for determining a power supply region of at least one of the standard cells being an outer standard cell of a respective row; and
means for arranging tracks for power supply up to the power supply region of the outer standard cell.
